(19) United States
(12) Patent Application Publication
(10) Pub. No.: US 2026/0022975 A1
(43) Pub. Date: Jan. 22, 2026

(54) TEMPERATURE SENSOR

(71) Applicant: Aktiebolaget SKF, Goteborg (SE)

(72) Inventors: Sheng FAN, Shanhai (CN); Xing YI, Shanghai (CN); Yeda WAN, Shanghai (CN); Chenguang WANG, Shanghai (CN); Shuaihua WU, Shanghai (CN)

(21) Appl. No.: 19/265,442

(22) Filed: Jul. 10, 2025

(30) Foreign Application Priority Data
Jul. 17, 2024 (CN) 202410957124.2

(51) Int. Cl. G01K 1/14; G01K 1/08; H05K 1/18

(52) U.S. Cl. CPC G01K 1/14; G01K 1/08; H05K 1/181; H05K 2201/10037; H05K 2201/10098

(57) ABSTRACT

A temperature sensor includes a base for mounting to a part to be sensed. A temperature sensitive element is mounted to the base. A circuit board is mounted to the base. The temperature sensitive element (2) is electrically connected to the circuit board. The temperature sensor eliminates the conventional structure of mounting a temperature-sensitive element on a circuit board, but separates the temperature-sensitive element from the circuit board so as to be located as close as possible to the sensed component.

### CROSS-REFERENCE TO RELATED APPLICATION

This application claims priority to Chinese Application No. 202410957124.2, filed Jul. 17, 2024, the entirety of which is hereby incorporated by reference.

### FIELD

The present disclosure relates to a temperature sensor.

### BACKGROUND

Temperature sensors are widely used in various devices to sense the temperature of components to be sensed. With technology advancement and the increase of measurement requirements, some temperature sensors also need to, through their internal antennas, emit sensing signal to a receiving component or even to a cloud platform for further processing. Therefore, higher requirements are placed on the temperature sensing accuracy and signal emission quality of the temperature sensor.

There are many factors that affect the temperature sensing accuracy and signal emission quality of a temperature sensor. For example, more sensitive temperature-sensitive elements, higher power emission antennas, etc. can often be used, but these solutions may significantly increase the cost and structural complexity of the temperature sensor.

Therefore, there is a desire in the art for a solution that can improve the performance of temperature sensors at lower cost and simpler structure.

### SUMMARY

In response to the above-mentioned problems and needs, the present disclosure proposes a new technical solution, which solves the above problems and brings other technical effects by adopting the following technical features.

The present disclosure provides a temperature sensor comprising: a base for mounting to a part to be sensed; a temperature sensitive element mounted to the base; a circuit board mounted to the base and to which the temperature sensitive element (2) is electrically connected.

The temperature sensor proposed by the present disclosure eliminates the conventional structure of mounting a temperature-sensitive element on a circuit board, but separates the temperature-sensitive element from the circuit board so as to be located as close as possible to the sensed component.

### BRIEF DESCRIPTION OF THE DRAWINGS

FIG. 1 is an exploded view of a temperature sensor according to a preferred embodiment of the present disclosure;

FIG. 2 is a view of the interior of the assembled temperature sensor package;

FIG. 3 is a cross-sectional view taken along line A-A of FIG. 2;

FIG. 4 is an appearance view of the temperature sensor of FIG. 1.

### DETAILED DESCRIPTION

In order to make the purpose, technical solution and advantages of the technical solution of the present disclosure clearer, the technical solution of the embodiment of the present disclosure will be described clearly and completely in the following with the attached drawings of specific embodiments of the present disclosure. Like reference numerals in the drawings represent like components. It should be noted that a described embodiment is a part of the embodiments of the present disclosure, not the whole embodiments. Based on the described embodiments of the present disclosure, all other embodiments obtained by those skilled in the field without creative labor fall into the scope of protection of the present disclosure.

In comparison with the embodiments shown in the attached drawings, feasible embodiments within the protection scope of the present disclosure may have fewer components, other components not shown in the attached drawings, different components, components arranged differently or components connected differently, etc. Furthermore, two or more components in the drawings may be implemented in a single component, or a single component shown in the drawings may be implemented as a plurality of separate components.

Unless otherwise defined, technical terms or scientific terms used herein shall have their ordinary meanings as understood by those skilled in the field to which this disclosure belongs. The terms “first”, “second” and similar terms used in the specification and claims of the patent application of this disclosure do not indicate any order, quantity or importance, but are only used to distinguish different components. When the number of components is not specified, the number of components can be one or more. Similarly, terms such as “a/an”, “the” and “said” do not necessarily mean quantity limitation. Similar terms such as “including” or “comprising” mean that the elements or objects appearing before the terms cover the elements or objects listed after the terms and their equivalents, without excluding other elements or objects. Similar terms such as “installation”, “setting”, “connection” or “matching” are not limited to physical or mechanical installation, setting and connection, but can include electrical installation, setting and connection, whether directly or indirectly. “Up”, “down”, “left” and “right” are only used to indicate the relative orientation relationship when the equipment is used or the orientation relationship shown in the attached drawings. When the absolute position of the described object changes, the relative orientation relationship may also change accordingly.

As mentioned previously, the problem in the art is that it is difficult to obtain a temperature sensor with better performance through lower cost and simpler structure. Through research by the inventor of the present disclosure, it was found that the layout of the internal components of the temperature sensor had a significant impact on the performance of the temperature sensor.

For example, while a conventional temperature sensor is, by its base, mounted to a component to be sensed, a temperature-sensitive element in the temperature sensor is typically mounted directly on a circuit board, which in turn is mounted to the base of the temperature sensor. However, due to limitations such as installation space limitations, thickness of the circuit board and heat resistance of other components on it, there is usually a certain distance between the circuit board and the base. This not only makes the temperature-sensitive element far away from the sensed component, but also temperature may be transmitted to the temperature sensitive element through a variety of media, so this conventional layout prevents the temperature sensor from obtaining more accurate temperature data.

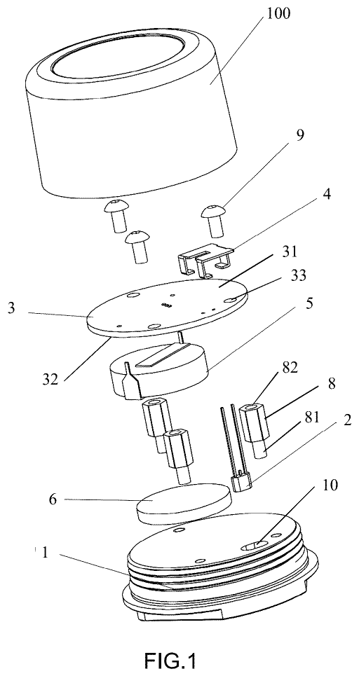

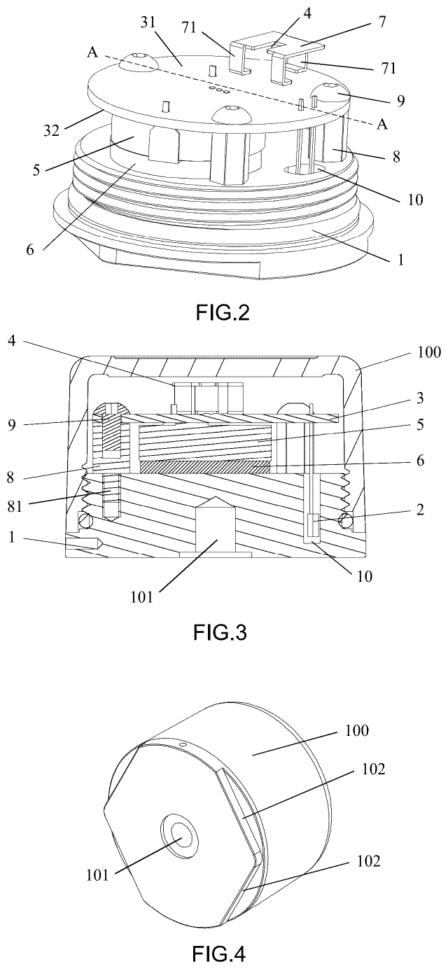

Therefore, the present disclosure provides a temperature sensor, as shown in FIGS. 1 and 2, which includes: a base 1 for mounting to a component to be sensed; a temperature sensitive element 2 mounted to the base 1; the circuit board 3 is mounted to the base 1. The temperature sensitive component 2 is electrically connected to the circuit board 3. With this structure, the temperature-sensitive element 2 is not only separated from the circuit board but also directly mounted to the base 1, so that the temperature-sensitive element 2 is closer to the sensed component and temperature data closer to the real temperature of the sensed component can be obtained only by heat transfer from the base 1. The base 1 is preferably made of a metal material with high thermal conductivity or the like, to provide better heat conduction.

Further preferably, the base 1 may have a recess 10 in which the temperature sensitive element 2 is disposed. By disposing the temperature sensitive element 2 in the recess 10, the temperature sensitive element 2 is closer to the component to be sensed, and the recess 10 also thins the bottom wall of the base 1, which is more conducive to heat transfer. Therefore, under the condition that the rigidity of the base 1 is satisfied, the recess 10 can be made deeper as much as possible, so that the temperature sensitive element 2 is as close as possible to the component to be sensed. More preferably, a thermally conductive glue may be used to fill the gap between the temperature sensitive element 2 and the recess 10. Thermal conductive glue not only plays a good heat conduction role, but can also be used to firmly fix the temperature sensitive element 2 in the recess 10.

In addition, according to the inventor's research, an antenna used to emit the temperature sensing signal is also affected by other components in the temperature sensor. For example, the antenna is very susceptible to metal components, especially in conventional temperature sensors, where the antenna is also typically mounted to the circuit board, and thus, the antenna may be significantly affected by the metal base when the circuit board is relatively close to the metal base. In addition, the battery mounted to the circuit board may also have a significant impact on the antenna.

Therefore, according to a preferred embodiment of the present disclosure, there is a first spacing between the circuit board 3 and the base 1. Therefore, even if the antenna 4 of the temperature sensor (for example, a Bluetooth antenna) is directly mounted on the circuit board 3, and since the circuit board 3 is spaced apart from the base 1, the impact of the base 1 on the antenna 4 can be reduced.

Further preferably, the temperature sensor may comprise a pillar 8. As shown in FIGS. 1 and 3, one end of the pillar 8 is connected to the base 1 and the other end is connected to the circuit board 3 to fix the circuit board 3 to the base 1. Preferably, there are three or more pillars 8. Preferably, one end of the pillar 8 includes a threaded post 81 to screw into a corresponding threaded hole in the base 1, and the other end includes a threaded hole 82 so that the screw 9 passing through a through hole 33 in the circuit board 3 can be screwed into the threaded hole 82, to fix the circuit board 3 to the base 1. It should be understood that one end 81 of the pillar 8 may be connected to the base 1 in other ways, such as by interference fit or welding. It should also be understood that the fixation of the pillar 8 to the circuit board 3 may be achieved by any other means. For example, in another embodiment not shown, the other end of the pillar 8 is also provided as a threaded post, which passes through the through hole 33 of the circuit board 3 and fastens the circuit board 3 through a nut.

Further preferably, in order to further reduce the interference suffered by the antenna 4, the antenna 4 may be mounted to a face 31 of the circuit board 3 facing away from the base 1, with a second spacing between the antenna 4 and the circuit board 3, as shown in FIGS. 2 and 3 shown. Preferably, the temperature sensor may further comprise an antenna platform 7 having legs 71 connected to the circuit board 3, as shown in FIG. 2. For example, there may be three or more legs 71. In turn, the antenna 4 may be mounted to or integrally formed with the antenna platform 7.

Therefore, the second spacing may be set as large as possible while satisfying mounting and dimensional requirements. With this arrangement, due to the presence of the first spacing between the circuit board 3 and the base 1 and the second spacing between the antenna 4 and the circuit board 3 as described above, the antenna 4 is further away from the base 1, so that impact from other components on the base 1 and the circuit board 3 is minimized.

Further, the temperature sensor also includes a battery 5, which is mounted to a face 32 of the circuit board 3 facing the base 1. That is to say, the battery 5 and the antenna 4 are located on both faces of the circuit board 3 respectively, further reducing the impact of the battery 5 on the antenna 4. According to a further preferred embodiment not shown, the battery 5 may have a third spacing from the circuit board 3 (for example the battery 5 may be soldered to the circuit board 3 by longer pins so that the battery 5 does not stick to the circuit board 3), thereby further increasing the distance between the antenna 4 and the battery 5. Further preferably, the third spacing is filled with fixing glue, preferably silicone glue or epoxy glue. Thus, by filling the fixing glue in the third spacing, particularly in the case where the temperature sensor is used under strong vibration, it is possible to further fix the battery 5 and the circuit board 3, and to exert an anti-vibration effect.

Further preferably, the temperature sensor further comprises a cushion 6 disposed between the battery 5 and the base 1. Since the temperature sensor may be applied to vibrating components, the cushion pad 6 can reduce the vibration transmitted to the battery 5 and prevent the soldering between the pins of the battery 5 and the circuit board 3 from loosening. The cushion 6 can be made of any suitable material, such as foam, rubber, resin, etc., and can be connected to the battery 5 and the base 1 by adhesive or the like. According to a more preferred embodiment, the cushioning pad 6 can be a silicone foam, which has better cushioning, insulation and high temperature resistance.

In addition, the temperature sensor also includes a housing 100 that matches with the base 1 (for example by screwing) to enclose the components of the temperature sensor. Preferably, the surface of the housing 100 has a surface resistivity of less than 10¹⁰Ω and greater than 10⁶Ω. Therefore, the such designed housing will not accumulate too much charge during operation, meeting explosion-proof requirements in some working scenarios. The base 1 may include a bottom connection hole 101 to facilitate mounting the temperature sensor to the component to be sensed. Bottom edges of the base 1 may include a plurality of straight edges 102 to facilitate engagement by an installation tool, such as a wrench.

In view of the above, the present disclosure proposes a temperature sensor, which eliminates a conventional structure of mounting a temperature sensitive element on a circuit board, but separates the temperature sensitive element from the circuit board so as to be located as close as possible to the sensed component. Furthermore, the antenna is also mounted at a distance from the base and the circuit board, minimizing interference from other components, especially metal components.

The exemplary embodiments of the present disclosure have been described in detail above with reference to preferred embodiments. However, those skilled in the art will understand that various modifications and modifications can be made to the above specific embodiments without departing from the concept of the present disclosure. Modifications, and various technical features and structures proposed in the present disclosure can be made in various combinations without exceeding the scope of protection of the present disclosure, which is determined by the appended claims.

What is claimed is:

1. A temperature sensor comprising:
a base for mounting to a component to be sensed;
a temperature sensitive element mounted to the base;
a circuit board mounted to the base, the temperature sensitive element being electrically connected to the circuit board.

2. The temperature sensor of claim 1, wherein the base has a recess in which the temperature sensitive element is disposed.

3. The temperature sensor of claim 2, further comprising a thermally conductive glue in a gap between the temperature sensitive element and the recess.

4. The temperature sensor of claim 1, wherein the circuit board is spaced apart from the base by a first spacing.

5. The temperature sensor of claim 4, further comprising a pillar connected at one end to the base and connected at the other end to the circuit board to fix the circuit board to the base.

6. The temperature sensor of claim 1, further comprising an antenna supported by a face of the circuit board facing away from the base, the antenna being spaced apart from the circuit board by a second spacing.

7. The temperature sensor of claim 6, further comprising an antenna platform having legs connected to the face of the circuit board.

8. The temperature sensor of claim 7, wherein the antenna is mounted to or integrally formed with the antenna platform.

9. The temperature sensor of claim 1, further comprising a battery mounted to a face of the circuit board facing the base.

10. The temperature sensor of claim 9, further comprising a housing, the surface of the housing having a surface resistivity of less than 10¹⁰Ω and greater than 10⁶Ω.

11. The temperature sensor of claim 1, further comprising a battery disposed between the circuit board and the base, wherein the battery is spaced apart from the circuit board by a third spacing.

12. The temperature sensor of claim 11, wherein the third spacing is filled with a fixing glue.

13. The temperature sensor of claim 12, wherein the fixing glue is silicone or epoxy glue.

14. The temperature sensor of claim 9, further comprising a cushion pad disposed between the battery and the base.

15. The temperature sensor of claim 14, wherein the cushion pad is a silicone foam.

16. The temperature sensor of claim 4, further comprising:
a pillar connected at one end to the base and connected at the other end to the circuit board to fix the circuit board to the base;
an antenna supported by a face of the circuit board facing away from the base, the antenna being spaced apart from the circuit board by a second spacing; and
an antenna platform having legs connected to the face of the circuit board;
wherein the antenna is mounted to or integrally formed with the antenna platform.

17. The temperature sensor of claim 4, further comprising:
a battery mounted to a face of the circuit board facing the base;
a housing, the surface of the housing having a surface resistivity of less than 10¹⁰Ω and greater than 10⁶Ω; and
a silicone foam cushion pad disposed between the battery and the base.
